(19) United States
(12) Patent Application Publication
(10) Pub. No.: US 2025/0130293 A1
(43) Pub. Date: Apr. 24, 2025

(54) SOLDER BALL DETECTING DEVICE, PRINTED CIRCUIT BOARD, RADAR CHIP AND ELECTRONIC EQUIPMENT

(71) Applicant: Calterah Semiconductor Technology (Shanghai) Co., Ltd., Shanghai (CN)

(72) Inventors: Zhengdong LIU, Shanghai (CN); Wenting ZHOU, Shanghai (CN)

(21) Appl. No.: 19/001,396

(22) Filed: Dec. 24, 2024

Related U.S. Application Data
(63) Continuation-in-part of application No. PCT/CN2023/100265, filed on Jun. 14, 2023.

(30) Foreign Application Priority Data
Aug. 25, 2022 (CN) 202211028338.9

(51) Int. Cl. G01R 31/71; G01S 7/03; G01S 7/40

(52) U.S. Cl. CPC G01R 31/71; G01S 7/032; G01S 7/40

(57) ABSTRACT

Provided are a solder ball detecting device, a radar sensor, a radar chip and an electronic equipment. A signal pin of a radar chip is fixed to a printed circuit board by a solder ball. The solder ball detecting device include: a sampling unit, configured to collect a sampled signal from a circuit loop that includes the solder ball; and a detecting unit, configured to detect the sampled signal and to output state information reflecting a welding state of the solder ball based on the sampled signal, where the radar chip is configured to transmit critical signals of the related to object detection via the signal pin and the solder ball.

### CROSS REFERENCE TO RELATED APPLICATIONS

The present application is a continuation-in-part of PCT Patent Application No. PCT/CN2023/100265, entitled “SOLDER BALL DETECTING DEVICE, PRINTED CIRCUIT BOARD, RADAR CHIP AND ELECTRONIC EQUIPMENT,” filed Jun. 14, 2023, which claims priority to Chinese patent application No. 202211028338.9, entitled “SOLDER BALL DETECTING DEVICE, PRINTED CIRCUIT BOARD, RADAR CHIP AND ELECTRONIC EQUIPMENT,” filed Aug. 25, 2022, each of which is incorporated by reference herein in its entirety.

### TECHNICAL FIELD

The present disclosure relates to the technical field of chip detection, and more specifically, to a solder ball detecting device, a printed circuit board, a radar chip, and an electronic equipment.

### BACKGROUND

An integrated circuit chip is a miniature electronic structure with the required circuit function, which is formed by integrating required electronic components of a circuit on a substrate through a certain process design and using the packaging technology.

The integrated circuit chip needs to be welded to a printed circuit board when in use. Generally, the integrated circuit chip is welded to the printed circuit board by a solder ball to provide physical support and electrical connection between the integrated circuit chip and the printed circuit board.

However, in the manufacturing and actual use of the integrated circuit chip, the solder ball may have problems such as cold joint, solder skip, aging and disengagement, and other solder ball abnormalities. An abnormality in the solder ball may affect the normal use of the integrated circuit chip.

For example, a radar chip and a millimeter-wave chip are now generally welded to a printed circuit board by means of solder balls when in use. The quality of the solder balls has a significant impact on the impedance of the input/output of the radar chip (e.g., a millimeter-wave chip), which in turn has a significant impact on the performance of electromagnetic waves radiated.

### SUMMARY

The present disclosure provides a solder ball detecting device, a printed circuit board, a radio frequency chip, and an electronic equipment, which can detect a real-time state of a solder ball in the chip.

In some embodiments, a solder ball detecting device is provided. The solder ball detecting device is configured to be electrically connected to a solder ball and to detect a welding state of the solder ball that fixes a signal pin of a radar chip to a printed circuit board, the solder ball detecting device including: a sampling unit, configured to collect a sampled signal from a circuit loop that includes the solder ball; and a detecting unit, configured to detect the sampled signal and to output state information reflecting the welding state of the solder ball based on the sampled signal, where the radar chip is configured to transmit a critical signal related to object detection via the signal pin and the solder ball.

In some embodiments, a radar sensor is provided. The radar sensor includes a radar chip, a solder ball configured to fix the radar chip on a printed circuit board, and the solder ball detecting device as described above.

In some embodiments, a radar chip is provided. The radar chip includes the solder ball detecting device as described above.

In some embodiments, an electronic equipment is provided. The electronic equipment includes the radar sensor or the radar chip as described above.

### BRIEF DESCRIPTION OF THE DRAWINGS

In order to more clearly describe the technical solutions in the embodiments of the present disclosure, accompanying drawings to be used in the description of the embodiments will be briefly introduced below. Apparently, the accompanying drawings in the following description show merely some embodiments of the present disclosure, and a person of ordinary skill in the art can still derive other accompanying drawings from these accompanying drawings without creative efforts.

FIG. 1 is a schematic diagram illustrating the connection of a radar chip to a printed circuit board in the related art.

FIG. 2 is a schematic diagram illustrating the structure of a solder ball detecting device according to an exemplary embodiment of the present disclosure.

FIG. 3 is a schematic diagram illustrating welding states of a plurality of solder balls.

FIG. 4 is a schematic diagram illustrating a solder ball detecting device disposed on a radar chip according to an exemplary embodiment of the present disclosure.

FIG. 5 is a schematic diagram illustrating the connection of a plurality of solder balls to a solder ball detecting device according to an exemplary embodiment of the present disclosure.

FIG. 6 is a schematic diagram illustrating the structure of a radar sensor with a solder ball detecting device according to an exemplary embodiment of the present disclosure.

FIG. 7 is a schematic diagram illustrating a damage degree of a solder ball according to an exemplary embodiment of the present disclosure.

### DETAILED DESCRIPTION

The present disclosure provides a solder ball detecting device, a printed circuit board, a radar chip, and an electronic equipment, in which a real-time state of a solder ball in a chip can be detected.

Exemplary embodiments will now be described more fully with reference to the accompanying drawings. However, the exemplary embodiments can be implemented in various forms, and should not be construed as being limited to the embodiments set forth herein. Rather, providing these embodiments allows the present disclosure to be comprehensive and complete and conveys the idea of the exemplary embodiments in a comprehensive manner to those skilled in the art. Like reference numerals in the accompanying drawings denote same or similar parts, and thus repetitive descriptions will be omitted.

The described features, structures, or characteristics may be combined in one or more embodiments in any suitable manner. In the following description, many specific details are provided, thereby giving a full understanding of the embodiments of the present disclosure. However, those skilled in the art may understand that the technical solutions of the present disclosure can be implemented without one or more of these specific details, or that other manners, components, materials, devices, etc. may be adopted. In these cases, the well-known structures, methods, devices, implementations, materials, or operations will not be shown or described in detail.

In addition, terms “include” and “have,” or any variations thereof, are intended to cover non-exclusive inclusion. For example, a process, method, system, product or apparatus including a series of steps or units is not limited to the listed steps or units, but optionally also includes steps or units that are not listed, or optionally also includes other steps or units that are inherent to the process, method, product or apparatus.

Terms “first,” “second” and the like in the specification, the claims and the above- described accompanying drawings of the present disclosure are used to distinguish between different subjects, instead of describing a particular order.

The technical solutions of the present disclosure are clearly and completely described below in conjunction with the accompanying drawings in the embodiments of the present disclosure. Apparently, the described embodiments are part, but not all, of the embodiments of the present disclosure. Based on the embodiments in the present disclosure, all other embodiments obtained by those skilled in the art without creative efforts fall within the scope of protection of the present disclosure.

A radar sensor is configured with a radar chip and an antenna array, and a radar sensor chip utilizes a detection signal wave emitted by the antenna array and an echo signal wave received by the antenna array to measure a physical quantity between the radar sensor and a surrounding obstacle, such as at least one of a three-dimensional contour of the obstacle, a relative velocity, a relative angle or a relative distance.

In some electronic detection devices (such as a vehicle autopilot system, an intrusion detection system and an aircraft) including the above-mentioned radar chip, there is a high requirement for the stability of the radio frequency signal transmitted by the radar chip.

For example, stable transmission of the radio frequency signal from the radar chip is important for the detection accuracy of electronic detection equipment.

In an advanced driver assistance system, for example, the stability of the radio frequency signals emitted by the radar chip facilitates automatic driving control by a central controller of the ADAS based on the precise measurement data detected.

Therefore, the radar chip is required to maintain a self-test of solder balls, an internal circuit and the like of the radar chip after shipment. The solder ball test is used to prevent an abnormal welding state of the solder ball due to human factors (such as cold joint and solder skip of the solder ball) and/or environmental factors (such as aging and disengagement of the solder ball).

Currently, some examples in which a welding state of a solder ball is detected adopt an optical imaging method, such as ultrasound, X-ray, CT and infrared imaging. The optical imaging principle is utilized to video a state of the solder ball, and the state of the solder ball is detected by means of a preset computer image algorithm or manual recognition.

However, it is found that the following deficiencies exist in the detection of a state of the solder ball by means of optical imaging.

1. The above method can be adopted to further analyze a solder ball that has been preliminarily determined to be abnormal. However, the above method is not suitable for detecting an abnormality of a solder ball immediately when the circuit device is used, and thus real-time detection of a state of the solder ball cannot be achieved.

2. In detection of the state of the solder ball by optical imaging equipment, the welding state of the integrated circuit chip is required to be interrupted, which affects the normal work of the integrated circuit chip, especially interfering with radio frequency signal transmission and electromagnetic wave radiation.

3. Test equipment for optical imaging is relatively complex and bulky, making the detection work more complex.

Based on the above problems, an aspect of the present disclosure provides a solder ball detecting device for real-time detection of a signal change in a circuit to which a solder ball is connected, so as to determine the loss of the solder ball.

In actual products, a signal pin of the radar chip (e.g., the radar sensor chip) is fixed to a printed circuit board through a solder ball to achieve the electrical connection between a circuit inside the radar chip and an electrical component of the printed circuit board. For example, a radio frequency emission signal emitted by a signal emitter in the radar chip is transmitted to a transmitter on the printed circuit board through the solder ball; or a receiver disposed on the printed circuit board transmits a radio frequency receipt signal to a signal receiver in the radar chip through the solder ball.

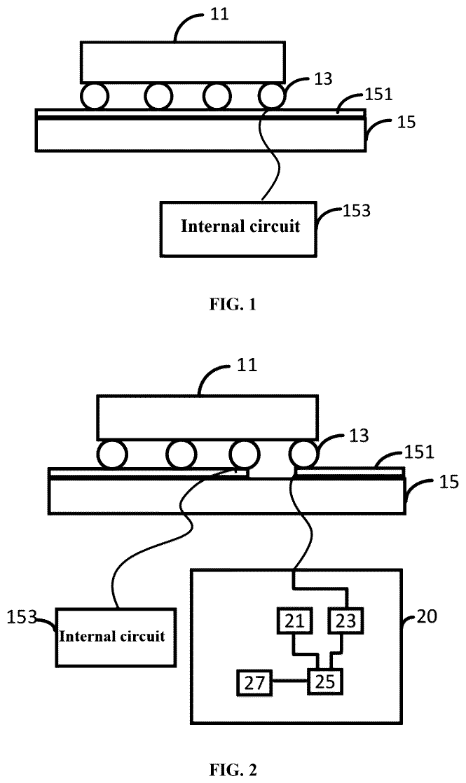

For example, FIG. 1 is a schematic diagram illustrating the connection between an existing radar chip and a printed circuit board. Referring to FIG. 1, FIG. 1 includes a radar chip 11, a solder ball 13 and a printed circuit board 15, with a copper cladding 151 provided on the printed circuit board 15.

The signal pin of the radar chip 11 is welded to the copper cladding 151 of the printed circuit board 15 by the solder ball 13 to electrically connect the radar chip 11 to the printed circuit board 15.

For example, a radio frequency signal emitted from a transceiver on the radar chip 11 is transmitted to the printed circuit board 15 through the solder ball 13 to transmit the radio frequency signal to an internal circuit 153 of the printed circuit board 15. The radio frequency signal is a frequency modulated continuous radio wave with a certain transmitting frequency. The internal circuit refers to a circuit of a radar sensor coupled to pins of the radar chip through solder balls to achieve the normal operation of the radar sensor, and for example, the internal circuit includes an antenna, a signal line, an oscillator, and the like. Taking FIG. 1 as an example, the internal circuit 153 is disposed on the printed circuit board 15. The copper cladding 151 is electrically connected to the internal circuit 153, and the radar chip 11 is electrically connected to the internal circuit 153 on the printed circuit board 15 by the solder ball 13, that is, the radar chip 11 is connected to the internal circuit 153, so as to ensure that the radar chip 11 can work normally through the internal circuit 153.

In another example, the internal circuit 153 may also be integrated in the radar chip and electrically connected to a circuit on the printed circuit board via a pin of the radar chip and a solder ball for fixing the pin. For example, the antenna is integrated into the package structure of the radar chip, and a ground pin of the antenna is fixed to the printed circuit board by means of a solder ball.

The radar chip emits a detection signal in a preset frequency band or at a fixed frequency and receive a radio frequency signal based on surroundings to be measured by the radar sensor. For example, the internal circuit includes at least one of a transmitter, a receiver, a local oscillation generating circuit, a clock signal generating circuit, a control signal generating circuit, or the like. The transmitter and the receiver are energy converters, which may be arranged together with the radar chip (e.g., a radar chip) on the printed circuit board (PCB). In the radar chip, the transmitter/receiver is electrically connected to a corresponding signal emitter/signal receiver by means of a solder ball, to form a radio frequency transmitting link/radio frequency receiving link. For example, the signal emitter is a millimeter-wave radio frequency transmitter circuit, and the signal receiver is a millimeter-wave radio frequency receiver circuit.

For a radar chip supporting chip cascading, internal circuits (such as the local oscillation generating circuit, the clock signal generating circuit and the control signal generating circuit) in the radar chip also have corresponding external terminals to be connected to the PCB by means of solder balls, so as to transmit corresponding signals to other radar chips.

Thus, detecting whether the solder ball is abnormal or not can promptly reflect the state of the connection between the radar chip and the external circuit. To this end, the present disclosure provides a solder ball detecting device (also referred to as a detecting circuit) for determining the state of a solder ball by detecting a sampling signal in a circuit loop formed by a solder ball and a circuit in the radar chip.

The solder ball detecting device constructs a detection circuit including a corresponding internal circuit and a solder ball and a ground line which are connected to the internal circuit to detect a welding state of the solder ball. The radar chip is configured to transmit a critical signal related to object detection via the signal pin and the solder ball. For example, the critical signal includes at least one of: a radio frequency transmitting signal and/or a radio frequency receiving signal of the radar sensor used to detect a surrounding object, or a plurality of synchronization signals (such as at least one of a local oscillation signal, a synchronization clock signal or a synchronization control signal) required for cooperative operations of the plurality of chips.

FIG. 2 is a schematic structure illustrating the structure of a solder ball detecting device according to an exemplary embodiment of the present disclosure. The solder ball detecting device is electrically connected to a solder ball, and configured to detect a welding state of the solder ball connected to a signal pin of a radar chip.

The solder ball detecting device 20 is electrically connected to a solder ball 13. The solder ball detecting device 20 includes a reference signal generating unit 21, a sampling unit 23, and a detecting unit 25.

According to an exemplary embodiment, the sampling unit 23 acquires a sampled signal of a circuit loop in which the solder ball is located. The sampling signal is exemplified as a level signal indicating the measured voltage/power. A part of the circuit loop is located on a PCB, and another part of the circuit loop is connected to the inside of the chip by means of the solder ball to be detected and a grounded solder ball. For example, a ground line of the circuit loop is a ground line on the PCB. In another example, the circuit loop contains a part of a radio frequency signal transmission path.

The sampling unit 23 may be configured on the PCB or inside the radar chip. In some examples, the sampling unit samples a power of the radio-frequency signal. For example, the sampling unit is a coupling circuit including a balun device, to acquire, by inductive coupling, a sampled signal representing a measured power. In other examples, the sampling unit samples a direct current signal. In another example, the sampling unit is a circuit including a voltage dividing resistor to acquire a sampled signal representing a measured voltage, or a direct-current voltage dividing signal. In another example, the sampling unit is a transmission line or the like which connects a frequency signal transmitting terminal/receiving terminal to a power supply.

In the above examples, the sampled signal includes: a measured voltage, a measured current, a measured power signal or the like of the circuit loop (e.g., a radio frequency circuit loop) in which the solder ball is located.

In other examples, the sampled signal includes a signal such as a current or a voltage generated in a detection circuit loop by a power supply. Taking as example the case where the solder ball to be detected is located on a radio frequency signal transmission circuit, the power supply in the detection circuit pours a DC signal into the solder ball to be detected, and the sampling signal collected by the sampling circuit includes a divided voltage or current of the DC signal.

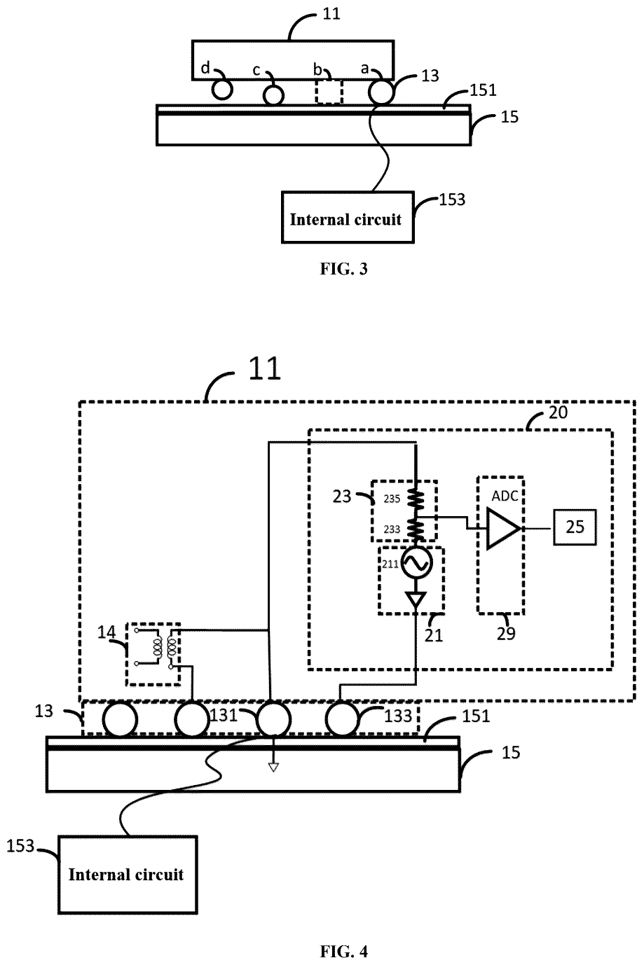

For example, FIG. 3 is a schematic diagram illustrating welding states of a plurality of solder balls. Four solder balls (i.e., solder ball a, solder ball b, solder ball c, and solder ball d) in different welding states are illustrated in FIG. 3.

The solder ball a is a solder ball whose welding state is the normal connection state, and has good contact with both the radar chip 11 and the printed circuit board 15.

The solder ball b is a solder ball whose welding state is the disengagement state, and is completely disengaged from the radar chip 11 and the printed circuit board 15.

A welding state of the solder ball between the normal connection state and the disengagement state is the abnormal connection state.

For example, the solder ball c and the solder ball d are solder balls whose welding states are in the abnormal connection state, and have the problem that an upper part of the solder ball is missing or a lower part of the solder ball is missing. The solder ball c and the solder ball d have poor contact performance with the radar chip 11 and the printed circuit board 15.

A welding state of the solder ball includes a normal connection state, a disengagement state, and an abnormal connection state. The disengagement state, such as cold joint and disengagement, may be indicated by an electrical characteristic of the circuit loop (in which the solder ball is located) being disconnected; the normal connection state, such as the solder ball being intact, may be indicated by an electrical characteristic of the circuit loop (in which the solder ball is located) whose electrical signal conforms to a preset threshold level in amplitude; and unlike the normal connection state, the abnormal connection state, such as the solder ball being partially disengaged, may be indicated by an electrical characteristic of the circuit loop which is disconnected and whose electrical signal does not conform to a preset threshold level in amplitude.

To this end, as shown in FIGS. 2 and 3, the reference signal generating unit 21 provides a reference signal capable of reflecting that an acquired sampled signal indicates at least one welding state of the solder ball, so as to distinguish at least two welding states. In some examples, the reference signal includes at least a first reference signal and a second reference signal.

For example, the first reference signal characterizes that a welding state of the solder ball is the normal connection state, and the second reference signal indicates that a welding state of the solder ball is the disengagement state. The first reference signal is a signal value obtained through practice in an actual application scenario to indicate that the solder ball is in a normal connection state with the radar chip and the printed circuit board. The second reference signal is a signal value obtained through practice in an actual application scenario to indicate that the solder ball is in a disengagement state with the radar chip and the printed circuit board. The first reference signal and the second reference signal can be known in advance based on the actual application scenario. For example, a reference signal is a reference voltage signal, or a reference current signal. The reference voltage signal includes a first reference voltage and a second reference voltage. The first reference voltage is a voltage value when a welding state of the solder ball is the normal connection state. The second reference voltage is a voltage value when a welding state of the solder ball is the disengagement state.

The reference signal generating unit 21 may be configured to provide a circuit for each reference signal separately. Alternatively, a power supply and multi-way voltage dividing circuits connected to the power supply are utilized to provide different reference signals respectively. For example, the reference signal generating unit includes a signal generator, a first resistor and a second resistor in series.

The detecting unit 25 detects the sampled signal using the reference signal to output state information reflecting a welding state of the solder ball.

The detecting unit 25 is configured to detect a received sampled signal by using a preset welding detection logic to output state information reflecting a welding state of the measured solder ball. For example, the welding detection logic is constructed according to a comparison result between a reference signal and a sampled signal and a logic based on the comparison result. For example, the welding detection logic is constructed by utilizing logic devices including a trigger and a gate circuit, or is an instruction set that performs sequential logic operations by a processor such as a microprogrammed control unit (MCU). For example, the state information is expressed by a binary signal of at least one bit, encoded data information, or the like.

In some examples, a reference signal and a sampled signal are each input to the detecting unit. The sampled signal is detected by the detecting unit based on a welding state corresponding to a respective reference signal. For example, the detecting unit includes a circuit configured by devices such as a comparator, a trigger and a logic gate, to detect a welding state of a detected solder ball corresponding to the received sampled signal in accordance with a preset signal processing logic, and to output state information.

The detecting unit detects a sampled signal using a reference signal to output state information reflecting a welding state of the solder ball.

Specifically, the detecting unit receives a sampled signal and a corresponding first reference signal and/or second reference signal separately, detects a signal difference between the sampled signal and the corresponding first reference signal and/or second reference signal to determine that a welding state of the solder ball is a normal connection state, a disengagement state or an abnormal connection state, and outputs corresponding state information. For example, as shown in FIG. 2, the reference signal generating unit 21 can provide at least one reference signal, and the sampling unit 23 samples a signal flowing through a solder ball to be detected. The reference signal generating unit 21 and the sampling unit 23 input to the detecting unit 25 for the detecting unit to perform a comparison of the signals, so as to output state information reflecting the detected solder ball.

For example, the sampled signal is a measured voltage Vr at the solder ball, the first reference signal is a first reference voltage V1 when a welding state of the solder ball is the normal connection state, and the second reference voltage signal is a second reference voltage V2 when a welding state of the solder ball is the disengagement state. The detecting unit determines relationships between a magnitude of the measured voltage Vr and magnitudes of the first reference voltage V1 and the second reference voltage V2. When the detecting unit determines that a voltage of the sampled signal is lower than a voltage of the second reference signal, it is determined that a welding state of the solder ball is a disengagement state, and corresponding state information is output. When the detecting unit determines that the voltage of the sampled signal is higher than the voltage of the first reference signal, it is determined that a welding state of the solder ball is a normal connection state, and corresponding state information is output. When the detecting unit determines that the voltage of the sampled signal is located between the voltage of the first reference signal and the voltage of the second reference signal, it is determined that a welding state of the solder ball is an abnormal connection state of semi-connection, and corresponding state information is output.

In other examples, the solder ball detecting device further includes an analog-to-digital converter (ADC), which may be coupled to an input end or an output terminal of the detecting unit. The ADC converts a received analog signal into a digital sampled signal for detection or generation of state information by the detecting unit.

For example, the ADC is located at a respective input end of the detecting unit to convert a sampled signal, a respective reference signal, a deviation signal or the like into a corresponding digital signal and provide the digital signal to the detecting unit. The detecting unit may be a data processor, such as an MCU, to perform detection of a welding state of a corresponding solder ball. In another example, the detecting unit performs subtraction of a sampled signal from a corresponding first reference signal and/or second reference signal to obtain a corresponding signal difference, and the detecting unit converts the signal difference by an ADC to a digital signal for digital signal processing based on a welding state, and thereby determines corresponding state information. In another example, the ADC converts the sampled signal into a digital signal, and the detecting unit detects the digital signal using a pre-stored first reference threshold and/or second reference threshold, thereby determining the state of the detected solder ball, where each reference threshold may represent a voltage domain under a different state of a solder ball.

In another example, the ADC is located at the output terminal of the detecting unit to encode an analog signal representing state information as a multi-bit digital signal, so as to indicate a detected welding state by an interval corresponding to at least one high bit in the digital signal. In other examples, the detecting circuit places the sampling unit and the solder ball to be detected in the same power environment, so that the sampling signal outputted by the sampling circuit varies due to the welding state of the solder ball. The detecting unit detects the sampling signal using a preset reference range to output the state information of the solder ball.

The sampling unit is connected in series, in parallel, or through a subtractor with a power supply, and a voltage difference/current difference reflecting the difference between the sampled signal and a power supply signal is provided in the formed path to serve as a deviation signal. The deviation signal is output to the detecting unit. The detecting unit determines a welding state of the detected solder ball by detecting at least one of a voltage value, a current value, a flow rate, or the like of the deviation signal, and outputs state information.

FIG. 4 exemplarily illustrates the structure of a solder ball detecting device according to an exemplary embodiment of the present disclosure. A transmission circuit 14 in the radar chip, for example, a balun, converts a radio frequency signal transmitted in a form of differential signal into a single-ended signal. The transmission circuit 14 is coupled and connected to the feed structure of the antenna via solder balls 131, 132, where the solder ball 132 is grounded. The radar chip usually includes a plurality of grounded solder balls, such as solder balls 132, 133. This facilitates the operation of the internal circuitry of the chip on the one hand, and on the other hand, facilitates the maintenance of consistent potentials referenced in different frequency band circuits.

The detection circuit includes: a power supply circuit 201, a sampling unit 203, a solder ball 131 to be detected, and a ground wire, where the output of the sampling unit is connected to an ADC 205 and a detecting unit 207.

The power supply circuit 201 is configured to provide a power supply signal (or referred to as a reference signal) into the detecting circuit. The power supply signal provides a reference such that the change in the sampled signal reflects a welding state of the solder ball under at least one loss condition. The power supply circuit 201 is, for example, a current source, a voltage source or a power supply provided by a chip power supply system.

A sampling unit 203 includes, for example, a voltage dividing resistor (e.g., a first resistor 233 and a second resistor 235) connected to an output terminal of a differential transmission circuit 14. The solder ball 131 is configured to transmit radio frequency signals from the radar chip, and is a solder ball to be detected. The sampling unit 203 is connected in series with the power supply circuit 201, and an output terminal is provided in the series path and connected to a detecting unit 207 via an ADC 205. In the case where the power supply circuit 201 supplies a stable voltage/current, the, the sampled signal output by the sampling unit 203 is related to the welding state of the solder ball 131. The sampled signal is converted into a digital signal by the ADC 205 and input to the detecting unit 207. The detecting unit 207 detects the welding state using digital logic.

Specifically, the sampled signal is output to the ADC, the ADC converts the sampled signal into a digital signal and inputs the digital signal into the detecting unit, the detecting unit can determine that a welding state of the solder ball 131 is at least one of a normal connection state, an abnormal connection state or a disengagement state by detecting a deviation between a voltage value of the digital signal and a voltage value of the reference signal. Taking the solder ball 131 being disconnected as an example, a voltage of the sampled signal output from the voltage dividing resistors 233, 235 is the same as a voltage of the reference signal, and the detecting unit can determine that a welding state of the solder ball 131 is the disengagement state by detecting a voltage value of the sampled signal.

It is to be noted that the determination on the sampled signal using the voltage range mentioned in the above respective examples is only an example, and subject to changes in the ambient temperature where the radar chip is located, the actual operating voltage, and the like, there should be a tolerable error between the sampled signal acquired and the reference signal used as a basis for the determination, so as to enable the detecting unit to obtain an equal (or matching) determination result within the corresponding error. Additionally and/or alternatively, the reference signal generating unit includes an adjustable circuit to adaptively adjust the output reference signal under the influence of process, voltage and temperature (PVT).

Optionally, the solder ball detecting device further includes an alarm unit configured to receive state information and issue an alarm message based on the state information indicating that the welding state is a disengagement state or an abnormal connection state.

Referring to FIG. 2, the solder ball detecting device 20 further includes an alarm unit 27. The alarm unit 27 is electrically connected to the detecting unit 25 to receive state information output by the detecting unit 25.

When the state information received by the alarm unit 27 is the disengagement state or the abnormal connection state, the alarm unit 27 issues an alarm message to alert the operator that the detected solder ball is abnormal, so as to enable the operator to view and maintain the abnormal solder ball in a timely manner.

In some examples, the solder ball detecting device is disposed on the printed circuit board and is electrically connected to the copper cladding of the printed circuit board. The solder ball is a solder ball that transmits a radio frequency signal in a circuit loop where the radar chip is located.

For example, referring to FIG. 2, the solder ball detecting device 20 is disposed on the copper cladding 151 so that the solder ball detecting device 20 can be electrically connected to the solder ball 13 on the copper cladding 151.

The solder ball 13 is a solder ball for transmitting a radio frequency signal in the circuit loop of the radar chip 11. The solder ball 13 receives a radio frequency signal through a signal pin of the radar chip 11 and transmits the radio frequency signal to the internal circuit 153 of the printed circuit board 15.

The internal circuit 153 is provided in parallel with the solder ball detecting device 20 on the copper cladding 151 electrically connected to the solder ball 13. Such configuration can make the solder ball detecting device 20 and the internal circuit 153 of the radar chip 11 independent and not interfere with each other. This allows the solder ball detecting device 20 to perform state detection of the solder ball without affecting the normal operation of the Radar chip 11.

In other examples, the solder ball detecting device is disposed on the radar chip and is electrically connected to the internal circuit within the radar chip that transmits the radio frequency signals.

For example, referring to FIG. 4, the solder ball detecting device 20 may also be disposed on the radar chip 11 and electrically connected to an internal circuit for transmitting the radio frequency signal within the radar chip 11. For example, referring to FIG. 4, the internal circuit for transmitting the radio frequency signal within the radar chip 11 includes a drive amplification circuit for the radio frequency signal. As shown in FIG. 4, the sampling unit 23 is coupled to a balun circuit 14, which is disposed at an output terminal of the drive amplification circuit to transmit a differential signal.

With the above exemplary embodiment, the solder ball detecting device 20 may be disposed on the printed circuit board 15 connected to a solder ball array 13, or may be disposed on the radar chip 11 to which the solder ball array 13 is connected. The specific location of the solder ball detecting device 20 is set according to different practical needs.

Optionally, the detecting unit further receives a self-test instruction from the radar chip and initiates state detection of a solder ball according to the self-test instruction.

For example, the detecting unit receives the self-test instruction from the radar chip, and a solder ball to be detected is connected to a radio frequency link in the radar chip, and is connected in the circuit loop in which the solder ball detecting device is located.

The radar chip sends out a self-test instruction, causing the radar chip to be in a self-test mode. The detecting unit initiates state detection of the solder ball in accordance with the self-test instruction. Taking the radar chip as an example, the radar chip generates a self-test instruction in a slot between adjacent valid chirp signals transmitted, or generates a self-test instruction when the radar chip is powered up and activated. The valid chirp signal refers to a frequency rise phase (or a frequency fall phase) of the chirp signal emitted by the radar chip, i.e., signal wave intervals for the radar chip to detect measurement data of a surrounding object such as a relative distance, a relative velocity and a relative angle; the other signal wave intervals of the chirp signal, as well as an idle interval between two chirp signals, are the slot between adjacent valid chirp signals. This achieves the purpose of the radar sensor to perform a self-check operation on a welding state of a solder ball during operation. An obtained detection result may be output to a signal processing circuit (e.g., a CPU or a buzzer), such as an alarm unit, so as to trigger, when a signal of the detection result indicates an abnormal welding state of the ball, an alert message for an user (or a remote user such as a customer service manager of a vehicle manufacturer) to be informed in a timely manner, or for a vehicle autopilot system, an aircraft or the like to adjust the level of confidence in data of a perception system.

With the above exemplary embodiments, the radar chip can self-trigger state detection of a solder ball. When the radar chip is applied to an electronic detection equipment such as a vehicle autopilot system or an aircraft, the vehicle autopilot system or aircraft is allowed to have a self-test mode, and can automatically detect information about a welding state of a solder ball on the vehicle autopilot system or aircraft.

This enables the vehicle autopilot system or aircraft to obtain normal/abnormal state information of a circuit loop in which a solder ball is located, and determine, based on the state information, whether or not alarm processing and emergency processing (such as adopting a certain compensation mechanism or switching an operating mode to cope with an abnormal accident) are required.

For example, when it is determined that an abnormality occurs in a solder ball connected to the radar chip, an operating mode of the solder ball is switched, and another alternative solder ball is selected for transmission of the radio frequency signal.

Optionally, the detecting unit also receives a preset instruction from the printed circuit board, and initiates state detection of a solder ball according to the preset instruction.

For example, the detecting unit receives a preset instruction from the printed circuit board, the preset instruction being a detection instruction set in accordance with a preset signal detection logic on the printed circuit board. For example, the preset instruction includes a start-up detection instruction, a specific solder ball detection instruction, and a detection logic sequence instruction.

The start-up detection instruction refers to on-demand triggering of state detection of a solder ball. The specific solder ball detection instruction includes state detection of only a solder ball for transmitting a radio frequency signal emitted from the radar chip. The detection logic sequence instruction refers to state detection of a solder ball in a certain preset order.

With the above exemplary embodiments, the solder ball detecting device can perform state detection of the solder ball based on the received self-test instruction from the radar chip, and the preset instruction from the printed circuit board, which can cope with the demand for state detection of a solder ball in different environments.

Optionally, the solder ball detecting device may be connected to one or more solder balls. After initiating state detection of a solder ball, the detecting unit 25 performs state detection of the solder ball according to the corresponding instruction.

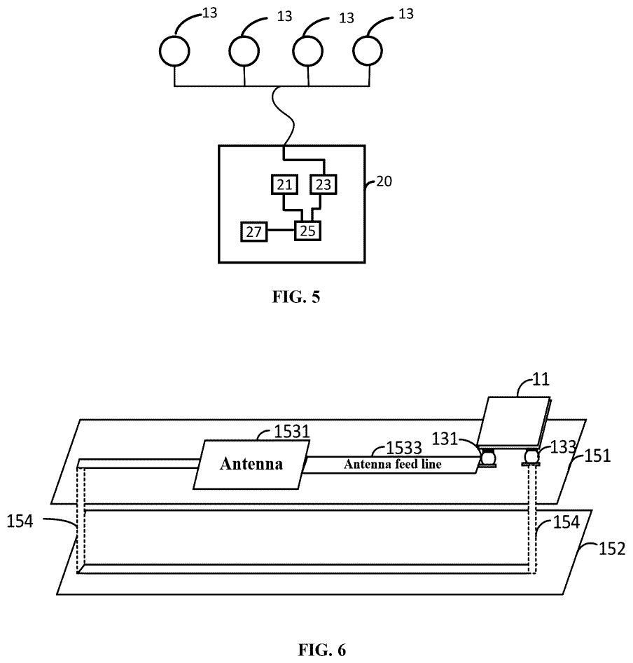

FIG. 5 is a schematic diagram illustrating the connection of a plurality of solder balls to a solder ball detecting device according to an exemplary embodiment of the present disclosure.

Referring to FIG. 5, the plurality of solder balls 13 are electrically connected to the solder ball detecting device 20 via lines. After the detecting unit 25 initiates state detection of a solder ball, the solder ball detecting device 20 switches, according to a preset signal detection logic, a sequence of communication with the plurality of solder balls 13 accordingly, to perform state detection of the plurality of solder balls 13.

For example, the preset signal detection logic may be to detect states of all solder balls 13, then the solder ball detecting device 20 completes state detection of all the solder balls 13 sequentially or simultaneously. Alternatively, the preset signal detection logic may be to detect a state of a specified solder ball 13, then the solder ball detecting device 20 accordingly completes state detection of the specified solder ball 13 sequentially or simultaneously.

FIG. 6 is a schematic diagram illustrating the structure of an internal circuit of a printed circuit board according to an exemplary embodiment of the present disclosure. In conjunction with FIGS. 2 and 6, the solder ball detecting device can detect a welding state of a solder ball to which an antenna 1531 is connected. One end of the antenna 1531 is connected to a solder ball 131 to be detected via an antenna feed line 1533.

The printed circuit board includes a first top layer 151, a second bottom layer 152, and a through hole 154. The other end of the antenna 1531 is electrically connected to a grounded solder ball 133 after passing through the first top layer 151 via a through hole 154 and passing through the second bottom layer 152 via another through hole 154.

According to an exemplary embodiment, a reference signal generated by the reference signal generating unit 21 shown in FIG. 2 is a reference voltage signal, and the reference voltage signal includes a first reference voltage and a second reference voltage.

For example, a sampled signal detected by the sampling unit 2 is a measured voltage Vr at the solder ball 13, the first reference voltage is a first reference voltage V1 when a welding state of a solder ball is a normal connection state, and the second reference voltage is a second reference voltage V2 when a welding state of the solder ball is a disconnection state. When the radar chip 11 is in the normal connection state with the printed circuit board 15, the measured voltage Vr is equal to the first reference voltage V1. When the radar chip 11 is in the disengagement state with the printed circuit board 15, the measured voltage Vr is equal to the second reference voltage V2. When the radar chip 11 and the printed circuit board 15 are in an abnormal connection state, the measured voltage Vr is between the first reference voltage V1 and the second reference voltage V2.

When the solder ball 13 is in the disengagement state, an equivalent disconnection exists at the solder ball 13, that is, the reference signal generating unit 21 is disconnected from the ground terminal, and at this time, a voltage value at the solder ball 13 is the reference signal generated by the reference signal generating unit 21, and the measured voltage Vr is equal to the second reference voltage V2.

When the solder ball 13 is in the abnormal connection state, that is, when the solder ball 13 is partially missing, the impedance at the solder ball 13 becomes larger, and thus will have a voltage dividing effect in conjunction with the first resistor 233 and the second resistor 235. Thus, at this time, the measured voltage Vr is greater than the first reference voltage V1, but does exceed the second reference voltage V2.

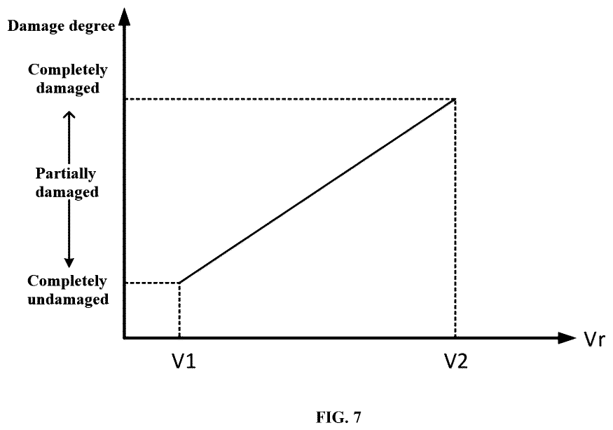

FIG. 7 is a schematic diagram illustrating a damage degree of a solder ball according to an exemplary embodiment of the present disclosure. In FIG. 7, the horizontal axis represents a sampled signal Vr, and the vertical axis represents a damage degree of the solder ball.

As can be seen from FIG. 7, when the measured voltage Vr is equal to the first reference voltage V1, the solder ball 13 is completely undamaged, that is, the welding state of the solder ball 13 is the normal connection state. When the measured voltage Vr is equal to the second reference signal V2, the solder ball 13 is completely damaged, that is, the welding state of the solder ball 13 is the disengagement state.

When the measured voltage Vr is between the first reference voltage V1 and the second reference voltage V2, the solder ball 13 is partially damaged, that is, the welding state of the solder ball 13 is the abnormal connection state.

Optionally, the sampling unit includes a first analog signal converter configured to convert a circuit analog signal into a digital signal to generate a sampled signal.

With the above exemplary embodiments, in the solder ball detecting device according to the technical solutions of the present disclosure, the reference signal is generated at the solder ball, the sampled signal is detected at the solder ball, and the welding state of the solder ball is reflected in the form of an electrical signal according to the magnitude relationship between the sampled signal and the reference signal, so that a current welding state of the solder ball can be intuitively and accurately determined.

The solder ball detecting device provided by the present disclosure has the advantages of being able to detect the state of the solder ball in real time, being able to determine the degree of damage to the solder ball, and the like, and is characterized by no influence on the normal operation of the radar chip during the detection process, small size and the like.

According to another aspect of the present disclosure, there is provided a radar sensor. The radar sensor includes a radar chip, a solder ball fixing the radar chip to a printed circuit board, and the above-described solder ball detecting device connected to the solder ball.

According to yet another aspect of the present disclosure, there is provided a radar chip which includes the above-described solder ball detecting device.

Optionally, the radar chip is a radar sensor chip applied to a radar sensor. Referring to the radar sensor shown in FIG. 6, the antenna 1531 and the antenna feed line 1533 of the radar sensor are arranged on the PCB 151, and the radar chip is fixed to the PCB 151 by solder balls 131, 133 and the like. To detect the solder ball 131, the solder ball 133 is connected to a radio frequency link in which the antenna 1531 is located via a transmission line of the PCB 151 and forms a circuit loop with the solder ball detecting device integrated in the radar sensor chip. In this way, in a certain time slot provided by the self-test system of the radar chip, the solder ball detecting device can detect the use of the solder ball 131 after the radar sensor chip is shipped from the factory, and output state information to a back-stage circuit.

According to yet another aspect of the present disclosure, there is provided an electronic equipment including the printed circuit board or radar chip as described above.

In an optional embodiment, the aforementioned electronic equipment may be components and products applied in fields such as intelligent residences, transportation, smart homes, consumer electronics, surveillance, industrial automation, in-cabin detection, and health care. For example, the electronic equipment may be smart transportation equipment (e.g., automobiles, bicycles, motorcycles, ships, subways and trains), security equipment (e.g., cameras), liquid level/flow rate detection equipment, smart wearable equipment (e.g., bracelets and glasses), smart home equipment (e.g., sweeping robots, door locks, televisions, air conditioners and smart lamps), various communication equipment (e.g., mobile phones and tablets), road gates, intelligent traffic lights, intelligent signs, traffic cameras, various industrialized mechanical arms (or robots), etc., and may also be various instruments for detecting vital signs parameters and devices equipped with such instruments, such as automotive cabin inspection, indoor personnel monitoring, intelligent medical devices and consumer electronic devices.

In yet another optional embodiment, when the above-described electronic equipment is applied to the ADAS, the radar sensor, as an in-vehicle sensor, can provide the ADAS with guarantee for a variety of functions such as autonomous emergency braking (AEB), blind spot detection (BSD) warning, lane change assist (LCA) and rear-cross traffic alert (RCTA).

Taking a vehicle configured with the ADAS as an example, the vehicle further includes a vehicle housing, and a vehicle drive system.

The vehicle housing is provided with at least one assembly hole. The at least one assembly hole is configured to assemble a radar sensor. The at least one assembly hole is provided at one or more positions on the vehicle housing depending on the need of the ADAS for measurement information provided by the radar sensor. For example, a plurality of assembly holes are provided at four body corner positions, and/or rearview mirror positions, etc. of the vehicle housing. The plurality of assembly holes may also be disposed directly in front and directly behind the vehicle, and/or door positions, etc.

A drive system of the vehicle is configured to drive the overall movement of the vehicle, such as forward, reverse and turn. For example, the drive system includes: an engine, a transmission mechanism, and wheels.

The ADAS is configured to provide warning information and/or to control the drive system of the vehicle to perform safety emergency operations based on the measurement information.

Herein, the ADAS includes a radar warning device (i.e., the aforementioned alarm unit) of the vehicle. Taking the radar sensor connected to a radar warning device as an example, when the radar sensor detects that the solder ball is in an abnormal state or in a disengagement state during the self-test process, then the radar sensor displays the abnormality of the device by means of the alarm unit, and can control the vehicle to decelerate, even to stop, or so on.

Finally, it should be noted that the above mentioned are only the preferred embodiments of the present disclosure, and are not intended to limit the present disclosure. Although the present disclosure is described in detail with reference to the foregoing embodiments, those skilled in the art may modify the technical solutions of the foregoing embodiments or make equivalent substitutions for some of the technical features therein. Any modifications, equivalent substitutions, improvements, etc. made within the spirit and principles of the present disclosure shall be included in the protection scope of the present disclosure.

What is claimed is:

1. A solder ball detecting device, configured to be electrically connected to a solder ball and to detect a welding state of the solder ball that fixes a signal pin of a radar chip to a printed circuit board, the solder ball detecting device comprising:
a sampling unit, configured to collect a sampled signal from a circuit loop that includes the solder ball; and
a detecting unit, configured to detect the sampled signal and to output state information reflecting the welding state of the solder ball based on the sampled signal;
wherein the radar chip is configured to transmit a critical signal related to object detection via the signal pin and the solder ball.

2. The solder ball detecting device according to claim 1, wherein the welding state of the solder ball is a normal connection state, a disengagement state, or an abnormal connection state.

3. The solder ball detecting device according to claim 1, wherein the detecting unit is configured to detect a deviation of a voltage of the sampled signal from a reference threshold and to output the state information based on the deviation.

4. The solder ball detecting device according to claim 1, wherein the solder ball detecting device further includes:
an alarm unit, configured to receive the state information and issue an alarm message based on the state information indicating that the welding state is a disengagement state or an abnormal connection state.

5. The solder ball detecting device according to claim 1, wherein the solder ball is disposed on a copper cladding layer of the printed circuit board, and the solder ball detecting device is disposed on the printed circuit board and electrically connected to the copper cladding layer of the printed circuit board.

6. The solder ball detecting device according to claim 1, wherein the critical signal includes at least one of the following:
at least one of a radio frequency transmit signal and a radio frequency receive signal for detecting a surrounding object; and
at least one of a local oscillation signal, a synchronization clock signal or a synchronization control signal required for cooperative operations of a plurality of chips.

7. The solder ball detecting device according to claim 1, wherein the detecting unit is further configured to initiate state detection of the solder ball according to a self-test instruction from the radar chip.

8. The solder ball detecting device according to claim 1, wherein the detecting unit is further configured to initiate state detection of the solder ball according to the preset instruction from the printed circuit board.

9. The solder ball detecting device according to claim 1, further comprising a power supply connected to the sampling unit, wherein the sampling unit is a voltage dividing circuit that outputs the sampled signal.

10. The solder ball detecting device according to claim 1, wherein the detecting unit includes: an analog signal converter configured to convert a received analog signal into a digital sampled signal for detection and generation of the state information at a digital side.

11. A radar sensor, comprising:
a radar chip;
a solder ball, configured to fix the radar chip on a printed circuit board; and
a solder ball detecting device, electrically connected to the solder ball and configured to detect a welding state of the solder ball, a signal pin of the radar chip being fixed to the printed circuit board by the solder ball, the solder ball detecting device comprising:
a sampling unit, configured to collect a sampled signal from a circuit loop in which the solder ball is located; and
a detecting unit, configured to detect the sampled signal to output state information reflecting the welding state of the solder ball;
wherein the radar chip is configured to transmit a critical signal related to object detection via the signal pin and the solder ball.

12. The radar sensor according to claim 11, wherein the welding state of the solder ball includes a normal connection state, a disengagement state, and an abnormal connection state.

13. The radar sensor according to claim 11, wherein the detecting unit is configured to detect a deviation of a voltage of the sampled signal from a reference threshold to output the state information.

14. The radar sensor according to claim 11, wherein the solder ball detecting device further includes:
an alarm unit, configured to receive the state information and issue an alarm message based on the state information indicating that the welding state is a disengagement state or an abnormal connection state.

15. The radar sensor according to claim 11, wherein the detecting unit is further configured to initiate state detection of the solder ball according to a self-test instruction from the radar chip or a preset instruction from the printed circuit board.

16. The radar sensor according to claim 11, wherein the critical signals include at least one of the following:
at least one of a radio frequency transmit signal and a radio frequency receive signal for detecting a surrounding object; and
at least one of a local oscillator signal, a synchronous clock signal, and a synchronous control signal required for cooperative operations of a plurality of chips.

17. A radar chip, comprising: a solder ball detecting device;
wherein the solder ball detecting device is electrically connected to a solder ball of the radar chip, and includes:
a sampling unit, configured to collect a sampled signal from a circuit loop in which the solder ball is located; and
a detecting unit, configured to detect the sampled signal to output state information reflecting a welding state of the solder ball;
wherein the radar chip is configured to transmit a critical signal related to object detection via the signal pin and the solder ball.

18. The radar chip according to claim 12, wherein the sampled signal includes at least one of: a measured voltage signal, a power level signal, or a direct current voltage dividing signal.

19. An electronic equipment, comprising the radar sensor according to claim 11.

20. An electronic equipment, comprising the radar chip according to claim 17.
